(19) United States
(12) Patent Application Publication
(10) Pub. No.: US 2018/0287344 A1
(43) Pub. Date: Oct. 4, 2018

(54) METHOD OF FABRICATING SURFACE-EMITTING LASER

(71) Applicant: SUMITOMO ELECTRIC INDUSTRIES, LTD., Osaka (JP)

(72) Inventor: Yukihiro Tsuji, Tama-shi (JP)

(73) Assignee: SUMITOMO ELECTRIC INDUSTRIES, LTD., Osaka (JP)

(21) Appl. No.: 15/906,607

(22) Filed: Feb. 27, 2018

(30) Foreign Application Priority Data
Apr. 4, 2017 (JP) 2017-074516

(51) Int. Cl. H01S 5/183; H01S 5/026

(52) U.S. Cl. CPC H01S 5/183; H01S 5/026

(57) ABSTRACT

A method of fabricating a surface-emitting laser includes the steps of preparing an epitaxial substrate that includes an active layer and an upper stacked semiconductor layer provided on the active layer, the upper stacked semiconductor layer including a structure for forming an upper distributed Bragg reflector; forming a mask for forming a semiconductor post on the epitaxial substrate; and etching the epitaxial substrate by dry etching using the mask. The step of etching the epitaxial substrate includes the steps of measuring photoluminescence from the epitaxial substrate in response to excitation light during the etching so as to monitor an end point of the dry etching in accordance with a result of the measuring; and ending the dry etching in response to detection of the end point.

### BACKGROUND OF THE INVENTION

### 1. Field of the Invention

The present invention relates to a method of fabricating surface-emitting lasers.

### 2. Description of the Related Art

Patent Literature 1 (Japanese Patent No. 5034662) discloses a method of fabricating a surface-emitting laser.

### SUMMARY OF THE INVENTION

In order to fabricate a post structure of a vertical cavity surface-emitting laser (VCSEL), a thick stacked semiconductor layer needs to be etched. In the VCSEL, the stacked semiconductor layer includes two distributed Bragg reflectors and an active layer disposed between the distributed Bragg reflectors. An end point of the etching relates to the height of the post structure. The post structure defines an optical resonator of the VCSEL. The height of the post structure is one of the most important parameters for designing the optical resonator of the VCSEL. In a process of etching the stacked semiconductor layer, detection of an appropriate end point is important for obtaining the desired post structure.

The stacked semiconductor layer for forming a VCSEL includes a plurality of semiconductor layers having different compositions and different thicknesses. It is not easy to detect the etching end point when a stacked semiconductor layer having such a complex structure is etched. Furthermore, the VCSELs have a plurality of post structures and stacked semiconductor layers for obtaining predetermined optical characteristics. In this case, the VCSELs have a variety of film thicknesses and types of layers. The structures of stacked semiconductor layers also vary. In a process of fabricating post structures of VCSELs, stacked semiconductor layers having such different structures need to be etched with good reproducibility. This further increases the difficulty in detecting the etching end point.

A method of fabricating a surface-emitting laser according to an aspect of the present invention includes the steps of preparing an epitaxial substrate that includes an active layer and an upper stacked semiconductor layer provided on the active layer, the upper stacked semiconductor layer being for forming an upper distributed Bragg reflector; forming a mask for forming a semiconductor post on the epitaxial substrate; and etching the epitaxial substrate by dry etching using the mask. The step of etching the epitaxial substrate includes the steps of measuring photoluminescence from the epitaxial substrate in response to excitation light during the etching so as to monitor an end point of the dry etching in accordance with a result of the measuring; and ending the dry etching in response to detection of the end point.

These and other objects, features, and advantages of the present invention will be more easily clarified from the following detailed description of a preferred embodiment of the present invention described with reference to the accompanying drawings.

### BRIEF DESCRIPTION OF THE DRAWINGS

FIG. 1 schematically illustrates a main step of a method of fabricating a surface-emitting semiconductor laser according to an embodiment.

FIG. 2 schematically illustrates a main step of the method of fabricating the surface-emitting semiconductor laser according to the present embodiment.

FIGS. 3A, 3B, and 3C schematically illustrate steps of fabricating a mask in the method of fabricating the surface-emitting semiconductor laser according to the present embodiment.

FIG. 4 schematically illustrates a main step of the method of fabricating the surface-emitting semiconductor laser according to the present embodiment.

FIG. 5 schematically illustrates an etching apparatus used for the method of fabricating the surface-emitting semiconductor laser according to the present embodiment.

FIGS. 6A, 6B, and 6C illustrate a photoluminescence (PL) monitor waveform for end point detection, an interference end point monitor waveform for end point detection, and an epitaxial structure when an epitaxial substrate according to an example is etched.

FIG. 7 schematically illustrates a main step of the method of fabricating the surface-emitting semiconductor laser according to the present embodiment.

FIG. 8 schematically illustrates a main step of the method of fabricating the surface-emitting semiconductor laser according to the present embodiment.

FIG. 9 schematically illustrates a main step of the method of fabricating the surface-emitting semiconductor laser according to the present embodiment.

FIG. 10 schematically illustrates a main step of the method of fabricating the surface-emitting semiconductor laser according to the present embodiment.

FIG. 11 schematically illustrates a main step of the method of fabricating the surface-emitting semiconductor laser according to the present embodiment.

### DESCRIPTION OF THE PREFERRED EMBODIMENTS

Continuing from the above description, some specific embodiments will now be described.

A method of fabricating a surface-emitting laser according to an embodiment includes the steps of preparing an epitaxial substrate that includes an active layer and an upper stacked semiconductor layer provided on the active layer, the upper stacked semiconductor layer including a structure for forming an upper distributed Bragg reflector; forming a mask for forming a semiconductor post on the epitaxial substrate; and etching the epitaxial substrate by dry etching using the mask. The step of etching the epitaxial substrate includes the steps of measuring photoluminescence from the epitaxial substrate in response to excitation light during the etching so as to monitor an end point of the dry etching in accordance with a result of the measuring; and ending the dry etching in response to detection of the end point.

According to the method of fabricating the surface-emitting laser, photoluminescence from the epitaxial substrate is measured by radiating the excitation light to the epitaxial substrate during etching the epitaxial substrate. The epitaxial substrate for forming the surface-emitting laser includes the upper stacked semiconductor layer provided on the active layer. The upper stacked semiconductor layer includes a structure for forming the upper distributed Bragg reflector. In the first half of the etching of the epitaxial substrate, part of the upper stacked semiconductor layer remains on the active layer. The residual part of the upper stacked semiconductor layer acts so as to confine photoluminescence in the active layer. In the second half of the etching of the epitaxial substrate, the residual film of the upper stacked semiconductor layer is substantially eliminated. As a result, the optical confinement effect of the second stacked semiconductor layer becomes weak remarkably, and strong photoluminescence is emitted from the active layer to the outside. However, when the etching further progresses, the active layer having a smaller thickness than that of the upper stacked semiconductor layer is eliminated in a short time period. As a result of the elimination of the active layer, the photoluminescence from the active layer is also lost. The measured values of such photoluminescence indicate changes in the intensity during the progress of the etching. These intensity changes relate to the exposure of the active layer during the progress of the etching. The measurement of the photoluminescence during the etching is utilized for detection of the end point. As has been described, the end point of the etching may be monitored in accordance with measurement results of photoluminescence. The etching of the epitaxial substrate is ended in response to detection of the end point.

In the method of fabricating a surface-emitting laser according to an embodiment, preferably, the epitaxial substrate includes a lower stacked semiconductor layer for forming a lower distributed Bragg reflector, and a contact layer provided between the lower stacked semiconductor layer and the active layer.

According to the method of fabricating the surface-emitting laser, the etching may be stopped in the contact layer in accordance with measurement results of photoluminescence.

In the method of fabricating a surface-emitting laser according to an embodiment, preferably, the end point is determined with reference to a peak of a strength of an optical spectrum in the measuring of the photoluminescence.

According to the method of fabricating the surface-emitting laser, when the residual film of the upper stacked semiconductor layer is substantially eliminated and before the etching of the active layer begins, the optical confinement effect of the upper stacked semiconductor layer is lost, and the strong photoluminescence from the active layer is temporarily observed.

In the method of fabricating a surface-emitting laser according to an embodiment, preferably, the epitaxial substrate includes a monitoring region provided for monitoring a progress of the etching. The monitoring region is irradiated with the excitation light so as to detect the photoluminescence.

In the method of fabricating a surface-emitting laser according to an embodiment, preferably, the active layer generates the photoluminescence in response to the excitation light. In addition, the upper stacked semiconductor layer includes a first semiconductor layer and a second semiconductor layer that are alternately stacked so as to form a distributed Bragg reflector.

Findings of the present invention can be easily understood in consideration of the following detailed description with reference to the accompanying drawings presented as examples. Next, an embodiment relating to a method of fabricating a semiconductor optical device such as a surface-emitting semiconductor laser will be described with reference to the accompanying drawings. Where possible, like reference signs denote like elements.

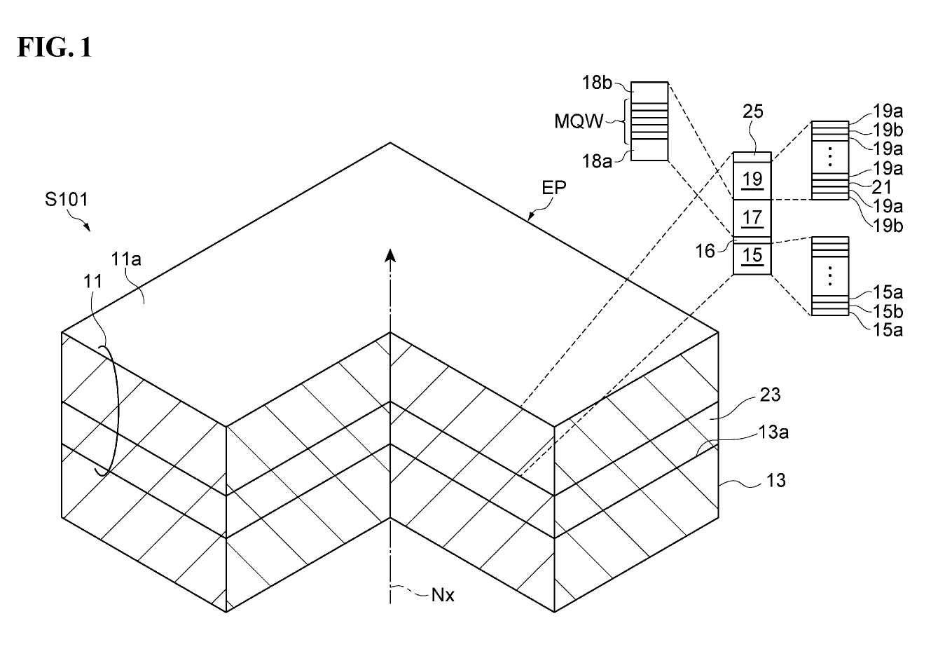

An example relating to a method of fabricating a surface-emitting semiconductor laser is described with reference to FIGS. 1 to 11. FIGS. 1, 2, 4, and 7 to 11 illustrate a single device section of the surface-emitting semiconductor laser in a wafer. The wafer includes a plurality of device sections of surface-emitting semiconductor lasers thereon. According to the present embodiment, for example, vertical cavity surface-emitting lasers (VCSELs) are fabricated.

As illustrated in FIG. 1, in step S101, an epitaxial substrate EP for forming the surface-emitting semiconductor lasers is prepared. The epitaxial substrate EP includes a substrate 13 having a principal surface 13a and a stacked layer 11 grown on the principal surface 13a of the substrate 13. Furthermore, the stacked layer 11 has a principal surface 11a. The stacked layer 11 includes a first stacked semiconductor layer 15 for forming a first distributed Bragg reflector, a semiconductor region 17 for forming an active layer, and a second stacked semiconductor layer 19 for forming a second distributed Bragg reflector. The first stacked semiconductor layer 15, a lower contact layer 16, the semiconductor region 17, and the second stacked semiconductor layer 19 are arranged in a direction of a normal axis Nx of the principal surface 13a of the substrate 13. The semiconductor region 17 includes a quantum well structure MQW for generating light. The second stacked semiconductor layer 19 includes, for example, an Al based III-V semiconductor layer 21 for forming current confinement structures. The lower contact layer 16 is provided between the first stacked semiconductor layer 15 and the semiconductor region 17. The stacked layer 11 of the epitaxial substrate EP may include either or both of a buffer layer 23 and an upper contact layer 25. Specifically, a semiconductor layer for forming the buffer layer 23 is provided between the first stacked semiconductor layer 15 and the substrate 13. A semiconductor layer for forming the upper contact layer 25 is provided on the second stacked semiconductor layer 19. In the present embodiment, the epitaxial substrate EP is fabricated by using the following processes. For fabricating the epitaxial substrate EP, first, the substrate 13 is prepared. The substrate 13 includes a semiconductor wafer. Specifically, the substrate 13 is a GaAs wafer W. The first stacked semiconductor layer 15 includes first semiconductor layers 15a and second semiconductor layers 15b. The first semiconductor layers 15a and the second semiconductor layers 15b are alternately stacked in the normal axis Nx direction so that the distributed Bragg reflector is configured. The lower contact layer 16 is grown on the first stacked semiconductor layer 15. After the first stacked semiconductor layer 15 has been grown, the semiconductor region 17 is grown. The second stacked semiconductor layer 19 includes third semiconductor layers 19a and fourth semiconductor layers 19b. The third semiconductor layers 19a and the fourth semiconductor layers 19b are alternately stacked in the normal axis Nx direction so that the distributed Bragg reflector is configured. The stacked layer 11 is grown by using, for example, either or both of a molecular beam epitaxy (MBE) method and a metal-organic vapor phase epitaxy (MOVPE) method.

An example of the epitaxial substrate EP
Buffer layer 23: undoped GaAs (thickness; 500 nm), undoped Al_{0.15}Ga_{0.85}As (thickness; 120 nm)
First stacked semiconductor layer 15: AlGaAs/AlGaAs super lattice
First semiconductor layer 15a: n-type Al_{0.15}Ga_{0.85}As, (thickness; 40 nm)
Second semiconductor layer 15b: n-type Al_{0.90}Ga_{0.10}As, (thickness; 45 nm)
Beginning and ending layers of the first stacked semiconductor layer 15 are the corresponding second semiconductor layers 15b.
Number of pairs in the first stacked semiconductor layer 15: 26
Lower contact layer 16: n-type Al_{0.10}Ga_{0.90}As, thickness; from 400 to 600 nm
Semiconductor region 17
Lower confinement layer 18a: undoped Al_{0.30}Ga_{0.70}As, (thickness; 90 nm)
Quantum well structure MQW: GaAs/Al_{0.30}Ga_{0.70}As, thickness; 50 nm (alternatively, AlGaInAs/AlGaAs or InGaAs/AlGaAs) Three well layers
Upper confinement layer 18b: undoped Al_{0.30}Ga_{0.70}As, (thickness; 90 nm)
Second stacked semiconductor layer 19: AlGaAs/AlGaAs super lattice
Third semiconductor layer 19a: p-type Al_{0.15}Ga_{0.85}As, (thickness; 40 nm)
Fourth semiconductor layer 19b: p-type Al_{0.90}Ga_{0.10}As, (thickness; 45 nm)
Al based III-V semiconductor layer 21: AlGaAs provided instead of Al_{0.90}Ga_{0.10}As
Number of pairs in the second stacked semiconductor layer 19: 23
Upper contact layer 25: p-type GaAs

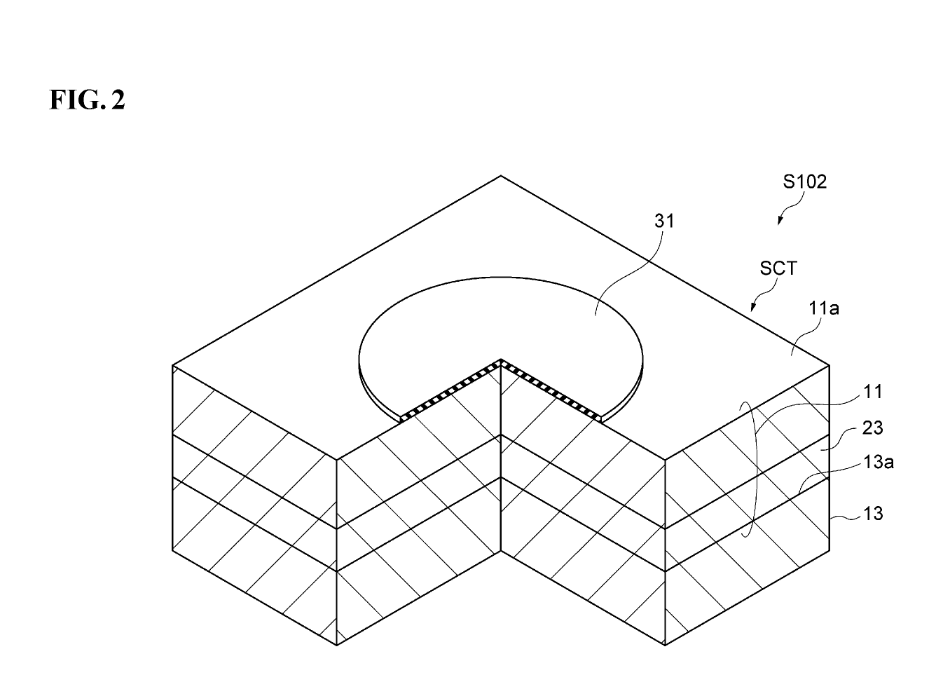

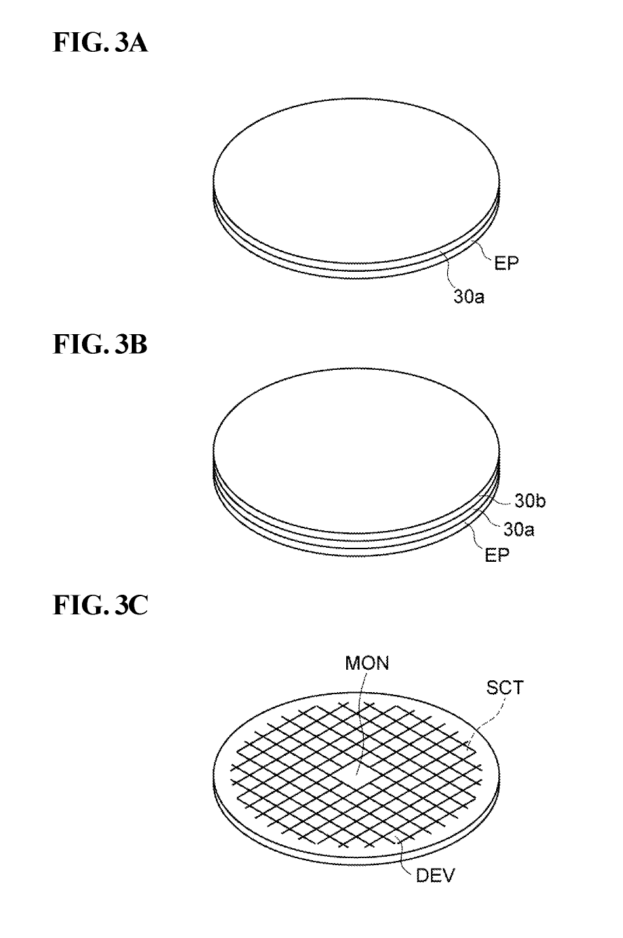

As illustrated in FIG. 2, in step S102, a mask 31 is formed on a principal surface of the epitaxial substrate EP. The mask 31 defines semiconductor posts. Specifically, for fabricating the mask 31, as illustrated in FIG. 3A, an inorganic insulating layer 30a is formed on the principal surface 11a of the stacked layer 11 of the epitaxial substrate EP. The inorganic insulating layer 30a is made of, for example, a silicon-based inorganic insulator such as a silicon oxide, a silicon nitride, or a silicon oxynitride. As illustrated in FIG. 3B, a resist mask 30b is formed on the inorganic insulating layer 30a by using a photolithography method. As illustrated in FIG. 3C, a pattern is formed in the inorganic insulating layer 30a by etching using the resist mask 30b so as to form the mask 31 having a pattern for the semiconductor posts. After the etching, the resist mask 30b is removed. The pattern of the mask 31 is formed on an epitaxial surface so as to match to an array of the device sections SCT. The array of the device sections SCT is included in a device region DEV. A monitoring region MON is provided for monitoring the progress of the etching in the device sections SCT arranged in an array. In the present embodiment, the monitoring region MON is surrounded by the array of the device sections SCT. When the monitoring region MON is irradiated with excitation light for measuring photoluminescence, sufficient monitor light for end point detection is obtained from the monitoring region MON. For example, the monitoring region MON has an area that may provide a size of at least 500-micrometer square.

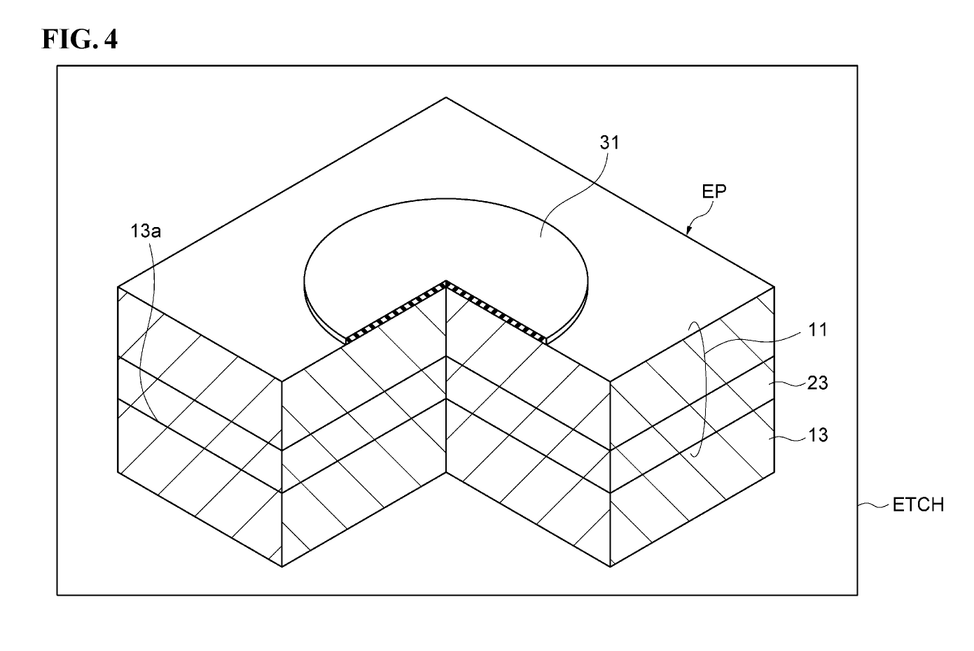

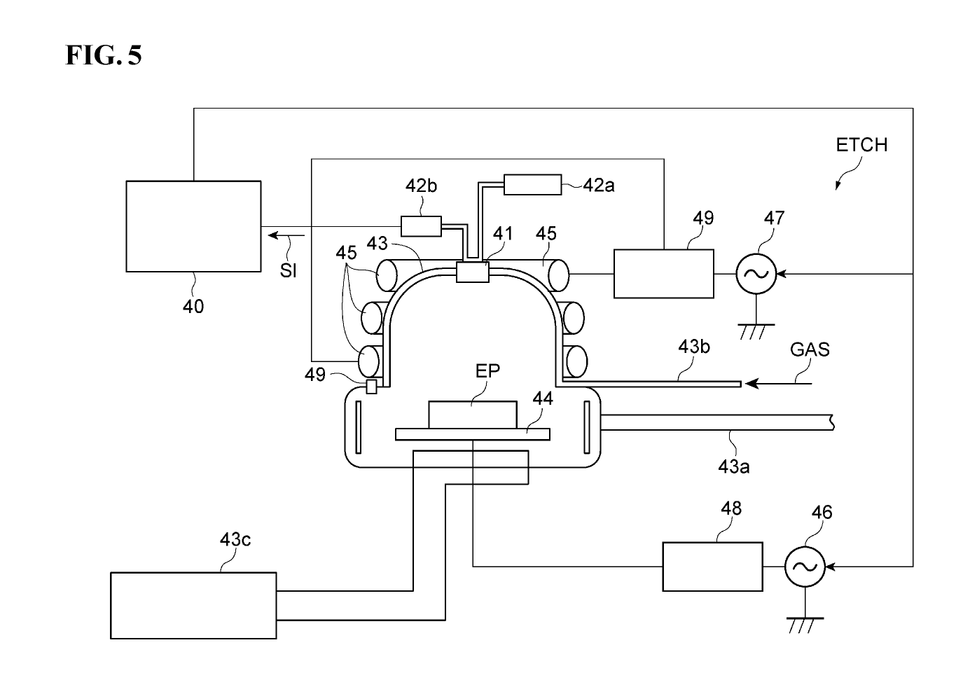

An etching apparatus is prepared in step S103. After the mask 31 has been formed, the epitaxial substrate EP is placed on an etching apparatus ETCH as illustrated in FIG. 4. FIG. 5 schematically illustrates an example of the etching apparatus usable for the present embodiment. The etching apparatus ETCH illustrated in FIG. 5 includes an inductive coupled plasma reactive ion etching (ICP-RIE) apparatus. This etching apparatus ETCH includes a viewport 41, an excitation light source 42a, an optical detector 42b, a chamber 43, a lower electrode 44, an inductive coupling coil 45, a first high-frequency power source 46, a second high-frequency power source 47, and a pressure gage 50. The excitation light source 42a and the optical detector 42b are used for measuring photoluminescence from the monitoring region MON in the epitaxial substrate EP to detect the end point of etching. The pressure gage 50 is, for example, a Baratron vacuum gage. The chamber 43 is connected to a discharge pump through a discharge channel 43a. The chamber 43 is also connected to a gas introduction system 43b for supplying gases GAS such as a process gas and a raw-material gas. The chamber 43 includes a dielectric dome. The inductive coupling coil 45 is provided outside the dielectric dome of the chamber 43. The lower electrode 44 is provided in the chamber 43 and allows the epitaxial substrate EP to be placed thereon. The first high-frequency power source 46 is connected to the lower electrode 44 through a first impedance matching box 48. The second high-frequency power source 47 is connected to the inductive coupling coil 45 through a second impedance matching box 49. In the present embodiment, the viewport 41 is provided at a ceiling of the dielectric dome. With this structure, the viewport 41 faces the lower electrode 44 (or the epitaxial substrate EP on the lower electrode 44). The excitation light source 42a radiates excitation light to an object through the viewport 41 of the etching apparatus ETCH. The optical detector 42b receives photoluminescence from the object through the viewport 41 of the etching apparatus ETCH. The optical detector 42b generates an electric signal SI corresponding to the intensity of the photoluminescence. The electric signal SI is received by a controller 40. In response to a change in intensity of the photoluminescence, the controller 40 performs determination on end point detection for etching. The active layer includes the quantum well structure MQW. When this quantum well structure MQW is irradiated with the excitation light, the quantum well structure MQW generates photoluminescence in response to the excitation light. The intensity of the photoluminescence from the quantum well structure MQW relates to a structure of stacked semiconductor layers (specifically, refractive index profile) disposed on the quantum well structure MQW. A stacked semiconductor layer (19) for forming the distributed Bragg reflector is disposed on the quantum well structure MQW in the epitaxial substrate EP. Through the viewport 41, the optical detector 42b receives the photoluminescence (at a wavelength of, for example, 810 nm) from the object being etched in response to the radiation of the excitation light source 42a (for example, Nd:YAG laser). With an end point monitoring using photoluminescence, the amount of a residual film of the stacked semiconductor layer for forming the distributed Bragg reflector is estimated during etching in accordance with the intensity of photoluminescence. Thus, end point detection of etching is performed by using photoluminescence from the epitaxial substrate EP in the etching process of the stacked semiconductor layer for forming the distributed Bragg reflector. Specifically, in response to supply of the electric signal SI corresponding to the intensity of the photoluminescence from the optical detector 42b, the controller 40 supplies a detection signal STP that instructs the etching apparatus ETCH to stop etching. The lower electrode 44 may be connected to a cooler 43c for temperature adjustment of the substrate during an etching step.

Furthermore, in step S103, the epitaxial substrate EP is placed on the lower electrode 44 of the etching apparatus ETCH as illustrated in FIG. 5. Furthermore, gas is discharged from the chamber 43 of the etching apparatus ETCH while supplying the process gas. A desired degree of vacuum is obtained for the chamber 43 by evacuating the chamber 43 using a discharge pump. After the chamber 43 has been evacuated, a gas containing the process gas and an etchant is supplied to the chamber 43. The process gas contains a diluent gas (either or both of He and Ar). The diluent gas does not contain chlorine as a constituent element.

As illustrated in FIG. 5, the excitation light source 42a and the optical detector 42b are mounted on the etching apparatus ETCH so as to couple the excitation light source 42a and the optical detector 42b to the viewport 41, optically. This viewport 41 is located above a wafer chuck on which the epitaxial substrate EP is placed. An end point detector is set up as follows. First, an image pickup device such as a charge-coupled device (CCD) camera is focused on and positioned with respect to a monitor area (for example, a monitor pattern) prepared in advance on the wafer. The monitor area has a desired size (for example, an area of 500-μm square) where the semiconductor is exposed. After the focusing and positioning have been performed, the excitation light source 42a and the optical detector 42b are optically coupled to the viewport 41 in place of the image pickup device.

After the excitation light source 42a and the optical detector 42b have been set up, etching is started. Specifically, plasma etching is performed on the epitaxial substrate EP is etched by using a plasma etching method. In this etching, a gas containing boron chloride and chlorine is supplied to the etching apparatus ETCH as an etchant. This etchant is used to etch both a device area and the monitor area in accordance with a pattern defined by the mask 31. Also, the monitor area includes the stacked layer 11. In fabrication of the VCSELs, a multi-layer structure is etched. In the first half of the etching, the second stacked semiconductor layer 19 and the semiconductor region 17 are processed. In the second half of the etching, the first stacked semiconductor layer 15 is processed.

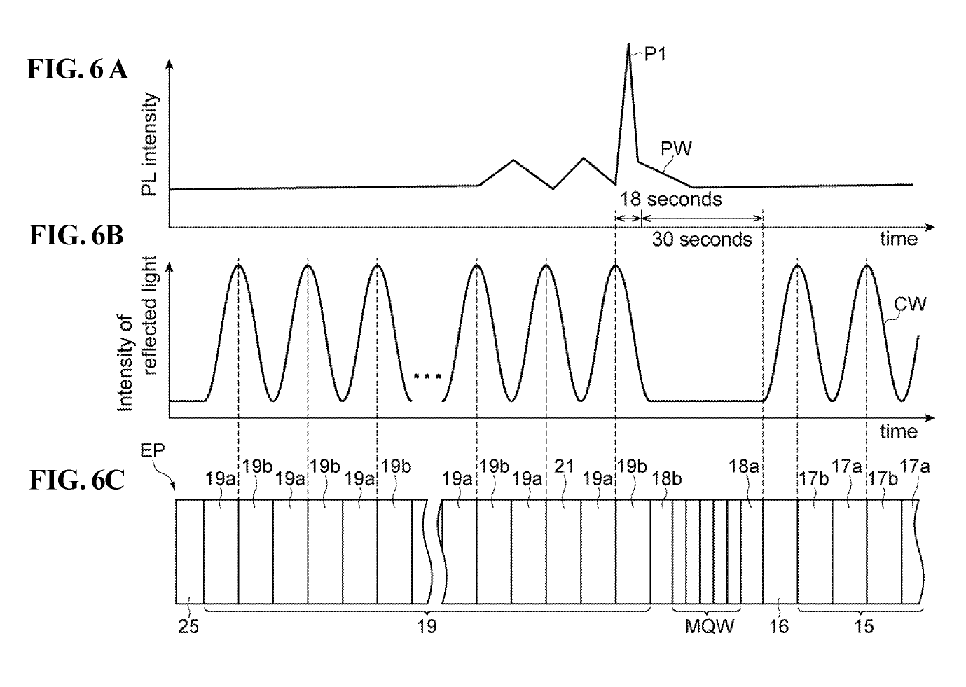

FIGS. 6A and 6B illustrate a photoluminescence (PL) waveform and an interference waveform for end point detection, respectively when the epitaxial substrate EP is etched. FIG. 6C illustrates the semiconductor layers of the stacked semiconductor layer disposed on the quantum well structure MQW in the epitaxial substrate EP. FIG. 6B illustrates an interference waveform CW obtained with an interference end point monitor when the epitaxial substrate EP is etched at an etching rate of 300 nm/min. For this etching, the epitaxial substrate EP is etched to the first stacked semiconductor layer 15 without performing end point detection during the etching to obtain the interference waveform CW indicated in FIG. 6B. FIG. 6A illustrates a PL waveform PW obtained with a PL monitor when the epitaxial substrate EP is etched at an etching rate of 300 nm/min. Also for this etching, the epitaxial substrate EP is etched to the first stacked semiconductor layer 15 without performing end point detection during the etching to obtain the PL waveform PW indicated in FIG. 6A. The shape of the PL waveform PW is related to the interference waveform CW and the semiconductor layers of the stacked semiconductor layer in the epitaxial substrate EP.

Photoluminescence is measured by using the optical detector 42b during the etching. Specifically, the optical detector 42b detects the photoluminescence emitted from the epitaxial substrate EP through the viewport 41 when the excitation light source 42a radiates the excitation light to the epitaxial substrate EP during the etching. The epitaxial substrate EP for forming the surface-emitting lasers includes the second stacked semiconductor layer 19 provided on the semiconductor region 17 for forming the active layer. In the embodiment, the second stacked semiconductor layer 19 includes the AlGaAs/AlGaAs super lattice for forming the upper distributed Bragg reflector of the surface-emitting laser. Specifically, the second stacked semiconductor layer 19 includes the third semiconductor layers 19a and the fourth semiconductor layers 19b that are alternately stacked. In the first half of the etching of the epitaxial substrate EP, part of the second stacked semiconductor layer 19 remains on the semiconductor region 17 (active layer). The residual part of the second stacked semiconductor layer 19 acts so as to confine light of photoluminescence in the active layer. As a result, an intensity of the photoluminescence emitted from the active layer to the outside is relatively small. In the second half of the etching of the epitaxial substrate EP, when the etching of a last one of the fourth semiconductor layers 19b begins, the optical confinement effect of the second stacked semiconductor layer 19 becomes weak remarkably. As a result, the strong photoluminescence P1 is emitted from the active layer in the semiconductor region 17 to the outside. When the residual film of the second stacked semiconductor layer 19 is substantially eliminated, the etching of the semiconductor region 17 including the active layer begins. However, when the etching further progresses, the active layer having a smaller thickness than that of the second stacked semiconductor layer 19 is eliminated in a short time period. As a result, the intensity of the photoluminescence from the active layer decreases with a decrease in thickness of the residual film of the active layer. The photoluminescence from the active layer is also lost when the active layer is eliminated. By measuring the intensity of such photoluminescence in the etching process, the progress of the etching can be recognized. These intensity changes relate to the exposure of the active layer during the progress of the etching and may be utilized for detection of the end point. As has been described, the end point of dry etching may be monitored in accordance with measurement results of photoluminescence and dry etching may be ended in response to detection of the end point.

### EXAMPLE

A time period for observing photoluminescence P1: 18 seconds
A time period after losing the photoluminescence P1 before start of the etching of the lower contact layer: 30 seconds

The end point detection may be determined after waiting for an elapse of time from detection of the photoluminescence P1. Specifically, the end point is determined with reference to a peak of the intensity of the optical spectrum in the measurement of photoluminescence. According to this method of fabricating, when the residual film of the upper stacked semiconductor layer is substantially eliminated, the optical confinement effect of the upper stacked semiconductor layer is also lost, and the strong photoluminescence from the active layer is temporarily observed before start of the etching of the active layer.

Meanwhile, the interference end point monitor utilizes the fact that the first stacked semiconductor layer 15 includes an AlGaAs/AlGaAs multi-layer and the substrate 13 includes a GaAs surface. In this method of fabricating and this method of monitoring by using the interference end point monitor, the end point detector detects the end point by receiving a beam of light reflected by the GaAs surface of the substrate and a beam of light reflected by the AlGaAs/AlGaAs multi-layer of the first stacked semiconductor layer 15 to be etched through the viewport 41. In addition, the end point detector detects the end point by utilizing interference light of these reflected beams.

The flow rate of BCl₃ is preferably 10 sccm (in standard condition (1 atm, 0 degrees centigrade), 6×10⁻⁴ m³/h (converted into the unit of the International System of Units (SI))) or smaller so that a boron compound is not excessively generated. Furthermore, the etchant is preferably diluted 9-fold or more with a process gas, for example, either or both of Ar and He. A chlorine gas Cl₂ is supplied to the chamber 43 so as to generate boron chloride (for example, BCl₃) from accumulated boron, and the boron chloride is reliably discharged from the chamber 43.

2B+3Cl₂→2BCl₃ (gas phase).

The flow ratios of the etching gas are, for example, BCl₃/Cl₂/Ar=8 sccm/2 sccm/90 sccm. Alternatively, the flow rations may be, for example, BCl₃/Cl₂/Ar=5 sccm/5 sccm/90 sccm. Furthermore, the supply mole ratio (MC/MB) of the molar quantity of chlorine (MC) to that of boron trichloride (MB) in the etchant supplied to the chamber 43 during the etching is 1 or larger. In addition, the supply mole ratio (MC/MB) of the molar quantity of chlorine (MC) to that of boron trichloride (MB) is 4 or smaller.

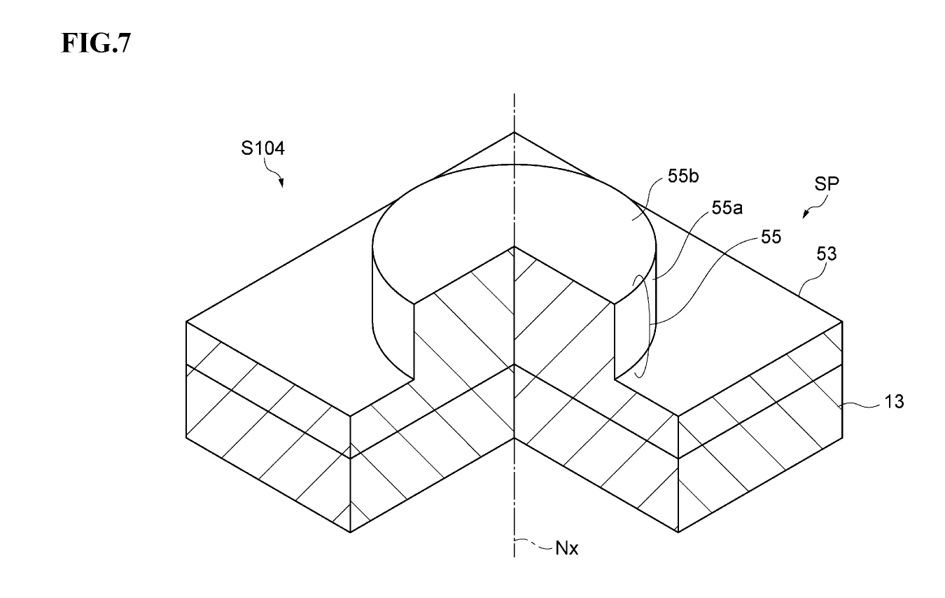

Main steps of the method of fabrication are further described. Substrate products SP are fabricated from the epitaxial substrate EP through the etching. After the substrate products SP have been removed from the etching apparatus ETCH, the mask 31 is removed in step S104 as illustrated in FIG. 7. Each of the substrate products SP includes the substrate 13 and a semiconductor structure 53. The semiconductor structure 53 includes a semiconductor post 55. The semiconductor post 55 includes the first distributed Bragg reflector, the active layer, and the second distributed Bragg reflector that are formed from the epitaxial structure of the epitaxial substrate EP. The first distributed Bragg reflector, the active layer, and the second distributed Bragg reflector are arranged in the normal axis Nx direction. The semiconductor post 55 has a side surface 55a that extends in the normal axis Nx direction and an upper surface 55b that extends along a plane intersecting the normal axis Nx direction.

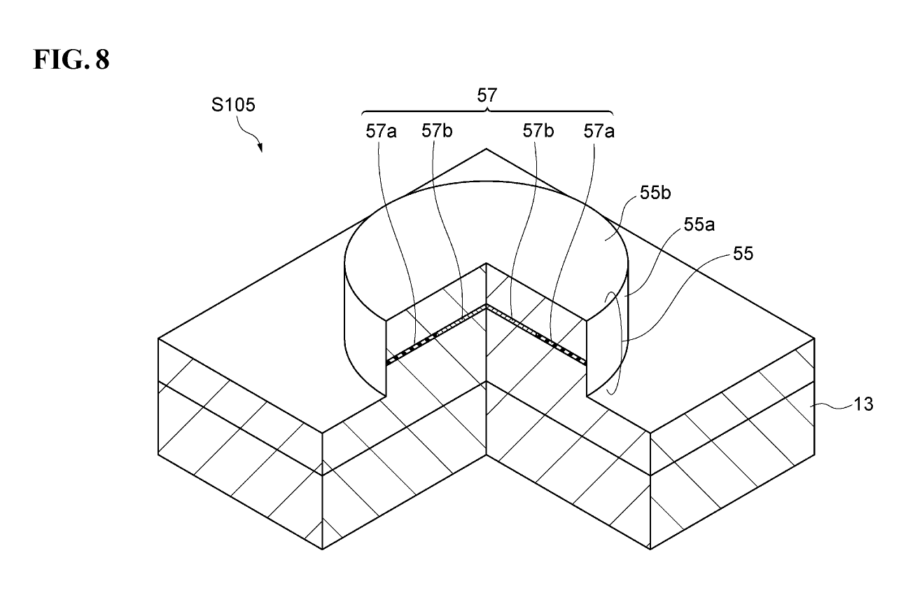

As illustrated in FIG. 8, in step S105, the substrate product SP is placed an oxidizing environment to form a current confinement structure 57. The semiconductor post 55 of the substrate product SP includes an AlGaAs layer having a large Al constituent. This AlGaAs layer having a large Al constituent is formed form the III-V semiconductor layer 21 of the stacked layer 11, and is provided between the active layer and the second distributed Bragg reflector layer. In the substrate product SP placed in the oxidizing environment, this AlGaAs layer (etched III-V semiconductor layer 21) is oxidized from the side surface 55a of the semiconductor post 55, thereby a group III oxide layer 57a (for example, aluminum oxide) is formed. Meanwhile, an AlGaAs window layer 57b remains. As a result, the group III oxide layer 57a surrounds the AlGaAs window layer 57b. The oxidizing environment includes, for example, high-temperature steam.

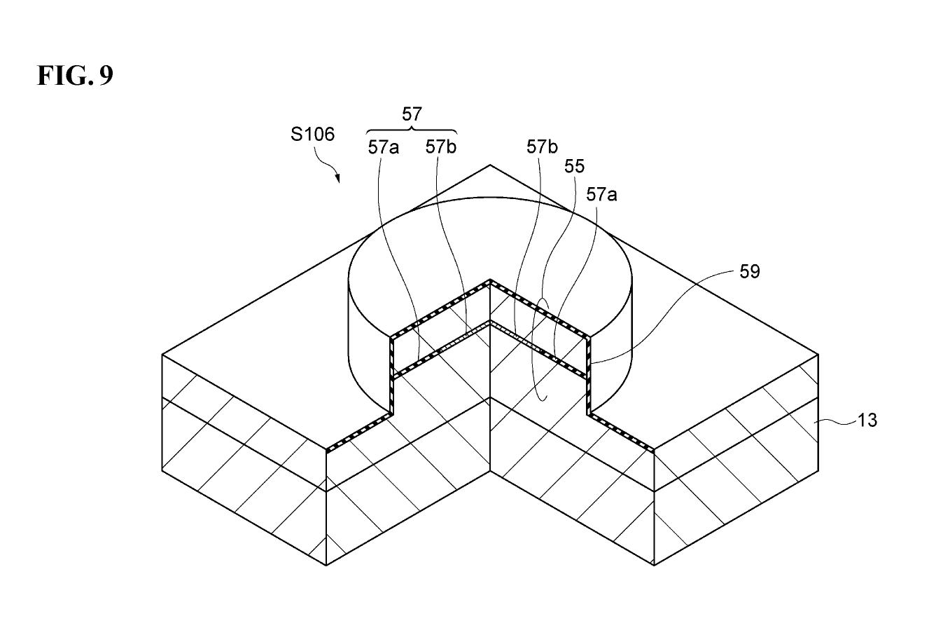

After the current confinement structure 57 has been formed, in step S106, a passivation film 59 is formed on the entire surface as illustrated in FIG. 9. The passivation film 59 is formed by using, for example, a plasma chemical vapor deposition (CVD) method. The passivation film 59 is made of a silicon-based inorganic insulator such as SiN, SiON, or SiO₂. The film thickness of the passivation film 59 may be adjusted so that the passivation film 59 is a high reflectivity film for the wavelength of light emitted by the surface-emitting semiconductor laser.

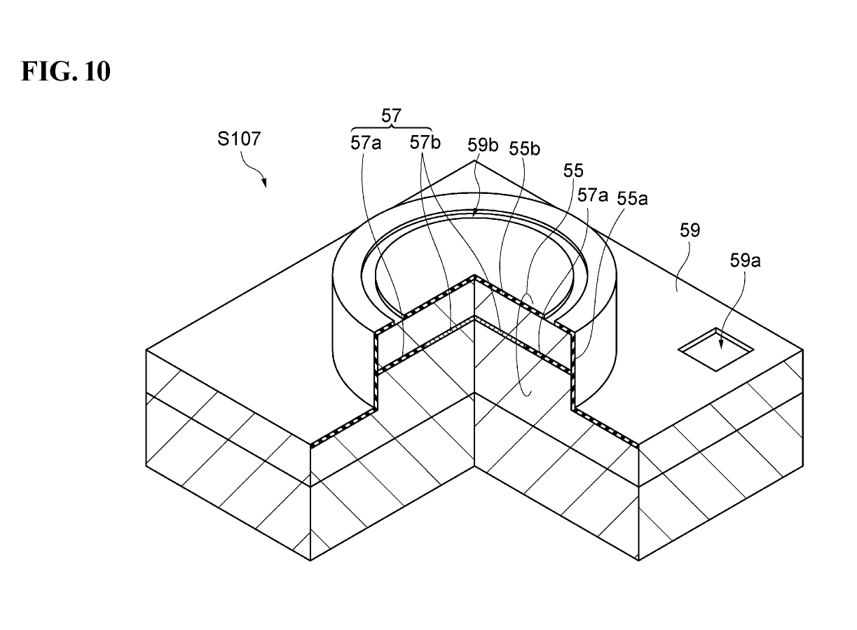

After the passivation film 59 has been formed, in step S107, openings for forming electrodes are formed in the passivation film 59 as illustrated in FIG. 10 by using an etching method and a photolithography method. In the embodiment, the passivation film 59 has a first opening 59a provided in the buffer layer 23 and a second opening 59b provided in the upper surface 55b of the semiconductor post 55.

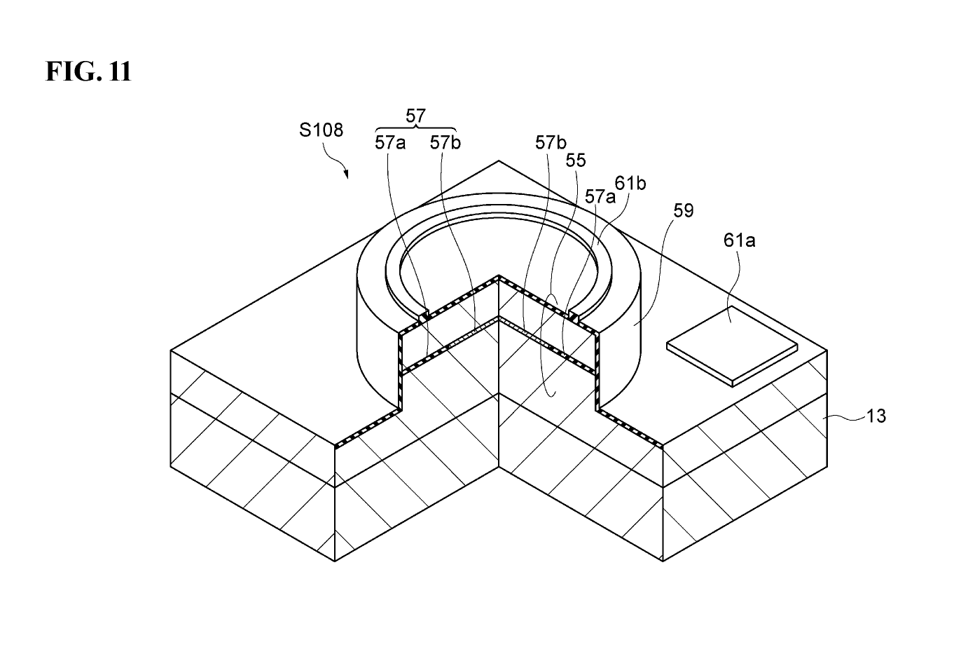

As illustrated in FIG. 11, after the passivation film 59 has been formed, in step S108, a first electrode 61a and a second electrode 61b are respectively formed in the first opening 59a and the second opening 59b. The first electrode 61a and the second electrode 61b each include a Ti/Pt/Au stack.

Through the above-described steps, a surface-emitting semiconductor laser is fabricated. The appearance of the completed surface-emitting semiconductor laser having a semiconductor chip shape is illustrated in FIG. 11.

Although the principles of the present invention have been illustrated and described with the preferred embodiment, it is appreciated by those skilled in the art that arrangement and details of the present invention can be changed without departing from such principles. The present invention is not limited to the specific structure disclosed for the present embodiment. Accordingly, a right is claimed for all modifications and changes derived from the claims and the scope of the gist of the claims.

What is claimed is:

1. A method of fabricating a surface-emitting laser, the method comprising the steps of:
preparing an epitaxial substrate that includes an active layer and an upper stacked semiconductor layer provided on the active layer, the upper stacked semiconductor layer including a structure for forming an upper distributed Bragg reflector;
forming a mask for forming a semiconductor post on the epitaxial substrate; and
etching the epitaxial substrate by dry etching using the mask,
wherein the step of etching the epitaxial substrate includes the steps of:
measuring photoluminescence from the epitaxial substrate in response to excitation light during the etching so as to monitor an end point of the dry etching in accordance with a result of the measuring; and
ending the dry etching in response to detection of the end point.

2. The method according to claim 1,
wherein the epitaxial substrate includes a lower stacked semiconductor layer for forming a lower distributed Bragg reflector, and
a contact layer provided between the lower stacked semiconductor layer and the active layer.

3. The method according to claim 1, wherein the end point is determined with reference to a peak of a strength of an optical spectrum in the measuring of the photoluminescence.

4. The method according to claim 1, wherein the epitaxial substrate includes a monitoring region provided for monitoring a progress of the etching, and
the monitoring region is irradiated with the excitation light so as to detect the photoluminescence.

5. The method according to claim 1, wherein the active layer generates the photoluminescence in response to the excitation light.

6. The method according to claim 1, wherein the upper stacked semiconductor layer includes a first semiconductor layer and a second semiconductor layer that are alternately stacked so as to form a distributed Bragg reflector.
